(19) United States
(12) Patent Application Publication
(10) Pub. No.: US 2022/0098092 A1
(43) Pub. Date: Mar. 31, 2022

(54) TRANSPARENT GLASS-CERAMIC ARTICLES HAVING IMPROVED MECHANICAL DURABILITY

(71) Applicant: CORNING INCORPORATED, CORNING, NY (US)

(72) Inventors: GEORGE HALSEY BEALL, BIG FLATS, NY (US); JOHN PHILIP FINKELDEY, ELKLAND, PA (US)

(21) Appl. No.: 17/482,774

(22) Filed: Sep. 23, 2021

Related U.S. Application Data
(60) Provisional application No. 63/083,238, filed on Sep. 25, 2020.

(51) Int. Cl. C03C 10/00; C03B 32/02; C03C 4/18; H05K 5/03; H05K 5/02; H05K 5/00

(52) U.S. Cl. CPC C03C 10/0054; C03B 32/02; C03C 4/18; C03C 2204/00; H05K 5/0217; H05K 5/0017; H05K 5/03

(57) ABSTRACT

A glass-ceramic article includes: from 40 wt % to 60 wt % SiO₂; from 18 wt % to 35 wt % Al₂O₃; from 12 wt % to 16 wt % B₂O₃; from 0 wt % to 4 wt % Li₂O; from 0 wt % to 5 wt % Na₂O; from 0 wt % to 5 wt % K₂O; from 0 wt % to 15 wt % ZnO; and from 0 wt % to 8 wt % MgO. The sum of Li₂O and Na₂O in the glass-ceramic article may be from 1 wt % to 8 wt %. The sum of MgO and ZnO in the glass-ceramic article may be from 3 wt % to 20 wt %. A predominate crystalline phase of the glass-ceramic article may comprise a mullite-type structure.

### CROSS-REFERENCE TO RELATED APPLICATION

This application claims the benefit of priority under 35 U.S.C. § 119 of U.S. Provisional Application Ser. No. 63/083,238 filed on Sep. 25, 2020, the content of which is relied upon and incorporated herein by reference in its entirety.

### FIELD

The present specification relates to glass-ceramic compositions and, in particular, to ion exchangeable glass-ceramic compositions.

### TECHNICAL BACKGROUND

Glass articles, such as cover glasses, glass backplanes, and the like, are employed in both consumer and commercial electronic devices such as LCD and LED displays, computer monitors, automated teller machines (ATMs), and the like. Some of these glass articles may include “touch” functionality which necessitates that the glass article be contacted by various objects including a user's fingers and/or stylus devices and, as such, the glass must be sufficiently robust to endure regular contact without damage, such a scratching. Indeed, scratches introduced into the surface of the glass article may reduce the strength of the glass article as the scratches may serve as initiation points for cracks leading to catastrophic failure of the glass.

Moreover, such glass articles may also be incorporated in portable electronic devices, such as mobile telephones, personal media players, laptop computers, and tablet computers. As such, the optical characteristics of the glass article, such as the transmittance of the glass article, may be an important consideration.

Accordingly, a need exists for alternative materials which have improved mechanical properties relative to glass while also having optical characteristics similar to glass.

### SUMMARY

According to a first aspect A1, a glass-ceramic article may comprise: greater than or equal to 40 wt % and less than or equal to 60 wt % SiO₂; greater than or equal to 18 wt % and less than or equal to 35 wt % Al₂O₃; greater than or equal to 12 wt % and less than or equal to 16 wt % B₂O₃; greater than or equal to 0 wt % and less than or equal to 4 wt % Li₂O; greater than or equal to 0 wt % and less than or equal to 5 wt % Na₂O; greater than or equal to 0 wt % and less than or equal to 5 wt % K₂O; greater than or equal to 0 wt % and less than or equal to 15 wt % ZnO; and greater than or equal to 0 wt % and less than or equal 8 wt % MgO, wherein: Li₂O+Na₂O is greater than or equal to 1 wt % and less than or equal to 8 wt %; MgO+ZnO is greater than or equal to 3 wt % and less than or equal to 20 wt %; and a predominate crystalline phase of the glass-ceramic article comprises a mullite-type structure.

A second aspect A2 includes the glass-ceramic article according to the first aspect A1, wherein the glass-ceramic article comprises greater than or equal to 12.5 wt % and less than or equal to 16 wt % B₂O₃.

A third aspect A3 includes the glass-ceramic article according to the second aspect A2, wherein the glass-ceramic article comprises greater than or equal to 13 wt % and less than or equal to 15.5 wt % B₂O₃.

A fourth aspect A4 includes the glass-ceramic article according to any of the first through third aspects A1-A3, wherein Li₂O+Na₂O is greater than or equal to 1.2 wt % and less than or equal to 6 wt %.

A fifth aspect A5 includes the glass-ceramic article according to the fourth aspect A4, wherein Li₂O+Na₂O is greater than or equal to 1.4 wt % and less than or equal to 5 wt %.

A sixth aspect A6 includes the glass-ceramic article according to any of the first through fifth aspects A1-A5, wherein MgO+ZnO is greater than or equal to 5 wt % and less than or equal to 18 wt %.

A seventh aspect A7 includes the glass-ceramic article according to the sixth aspect A6, wherein MgO+ZnO is greater than or equal to 7 wt % and less than or equal to 15 wt %.

An eighth aspect A8 includes the glass-ceramic article according to any of the first through seventh aspects A1-A7, wherein the glass-ceramic article comprises greater than or equal to 20 wt % and less than or equal to 30 wt % Al₂O₃.

A ninth aspect A9 includes the glass-ceramic article according to any of the first through eighth aspects A1-A8, wherein the glass-ceramic article comprises greater than or equal to 8 wt % and less than or equal to 15 wt % ZnO.

A tenth aspect A10 includes the glass-ceramic article according to any of the first through ninth aspects A1-A9, wherein (R₂O+RO)/Al₂O₃ is less than 1.

A eleventh aspect A11 includes the glass-ceramic article according to any of the first through tenth aspects A1-A10, wherein the glass-ceramic article is free of ZrO₂.

An twelfth aspect A12 includes the glass-ceramic article according to any of the first through eleventh aspects A1-A11, wherein the glass-ceramic article is free of As₂O₃.

A thirteenth aspect A13 includes the glass-ceramic article according to any of the first through twelfth aspects A1-A12, wherein the glass-ceramic article comprises greater than or equal to 40 wt % and less than or equal to 55 wt % SiO₂.

A fourteenth aspect A14 includes the glass-ceramic article according to the thirteenth aspect A13, wherein glass-ceramic article comprises greater than or equal to 43 wt % and less than or equal to 50 wt % SiO₂.

A fifteenth aspect A15 includes the glass-ceramic article according to any of the first through fourteenth aspects A1-A14, wherein a K_{1c} fracture toughness of the glass-ceramic article as measured by a double torsion method is greater than or equal to 0.90 MPa·m^{1/2}.

A sixteenth aspect A16 includes the glass-ceramic article according to any of the first through fifteenth aspects A1-A15, wherein an elastic modulus of the glass-ceramic article is greater than or equal to 50 GPa and less than or equal to 100 GPa.

A seventeenth aspect A17 includes the glass-ceramic article according to any of the first through sixteenth aspects A1-A16, wherein an average transmittance of the glass-ceramic article is greater than or equal to 70% and less than or equal to 95% of light over the wavelength range of 400 nm to 800 nm as measured at an article thickness of 0.8 mm.

An eighteenth aspect A18 includes the glass-ceramic article according to any of the first through seventeenth aspects A1-A17, wherein a coefficient of thermal expansion (CTE) of the glass-ceramic article is less than or equal to 50×10⁻⁷/° C.

According to a nineteenth aspect A19, a method of forming a glass-ceramic article may comprise: heating a glass-ceramic composition in an oven at a rate greater than or equal to 1° C./min and less than or equal to 10° C./min to a nucleation temperature, wherein the glass-ceramic composition comprises: greater than or equal to 40 wt % and less than or equal to 60 wt % SiO₂; greater than or equal to 18 wt % and less than or equal to 35 wt % Al₂O₃; greater than or equal to 12 wt % and less than or equal to 16 wt % B₂O₃; greater than or equal to 0 wt % and less than or equal to 4 wt % Li₂O; greater than or equal to 0 wt % and less than or equal to 5 wt % Na₂O; greater than or equal to 0 wt % and less than or equal to 5 wt % K₂O; greater than or equal to 0 wt % and less than or equal to 15 wt % ZnO; and greater than or equal to 0 wt % and less than or equal 8 wt % MgO, wherein: Li₂O+Na₂O is greater than or equal to 1 wt % and less than or equal to 8 wt %; and MgO+ZnO is greater than or equal to 3 wt % and less than or equal to 20 wt %; maintaining the glass-ceramic composition at the nucleation temperature in the oven for time greater than or equal to 0.25 hour and less than or equal to 4 hours to produce a nucleated crystallizable glass; heating the nucleated crystallizable glass in the oven at a rate greater than or equal to 1° C./min and less than or equal to 10° C./min to a crystallization temperature; maintaining the nucleated crystallizable glass at the crystallization temperature in the oven for a time greater than or equal to 0.25 hour and less than or equal to 4 hours to produce the glass-ceramic article, wherein a predominate crystalline phase of the glass-ceramic article comprises a mullite-type structure; and cooling the glass-ceramic article to room temperature.

A twentieth aspect A20 includes the method according to the nineteenth aspect A19, wherein the nucleation temperature is greater than or equal to 600° C. and less than or equal to 900° C.

A twenty-first aspect A21 includes the method according to the nineteenth aspect A19, wherein the crystallization temperature is greater than or equal to 700° C. and less than or equal to 1000° C.

A twenty-second aspect A22 includes the method according to the nineteenth aspect A19, further comprising strengthening the glass-ceramic article in an ion exchange bath.

A twenty-third aspect A23 includes the method according to the nineteenth aspect A19, wherein the glass-ceramic article has a K_{Ic} fracture toughness as measured by a double torsion method greater than or equal to 0.90 MPa·m^{1/2}.

A twenty-fourth aspect A24 includes the method according to the nineteenth aspect A19, wherein the glass-ceramic article has an elastic modulus greater than or equal to 50 GPa and less than or equal to 100 GPa.

A twenty-fifth aspect A25 includes the method according to the nineteenth aspect A19, wherein the glass-ceramic article has an average transmittance greater than or equal to 70% and less than or equal to 95% of light over the wavelength range of 400 nm to 800 nm as measured at an article thickness of 0.8 mm.

A twenty-sixth aspect A26 includes a consumer electronic device comprising: a housing having a front surface, a back surface, and side surfaces; electrical components provided at least partially within the housing, the electrical components including at least a controller, a memory, and a display, the display being provided at or adjacent the front surface of the housing; and the glass-ceramic article according to the first aspect A1 disposed over the display.

Additional features and advantages of the glass-ceramic compositions described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is a plan view of an exemplary electronic device incorporating any of the glass-ceramic articles according to one or more embodiments described herein;

FIG. 2 is a perspective view of the exemplary electronic device of FIG. 1;

FIG. 3 is a plot of an X-ray diffraction (XRD) spectrum (x-axis: Two-Theta angle; y-axis: Intensity) of an example glass-ceramic article made from a glass-ceramic composition and subjected to a heat treatment according to one or more embodiments described herein;

FIG. 4 is a scanning electron microscopy (SEM) image of an example glass-ceramic article made from a glass-ceramic composition and subjected to a heat treatment according to one or more embodiments described herein;

FIG. 5 is a plot of total transmittance (x-axis: Wavelength; y-axis: % Total Transmittance) of example glass-ceramic articles made from a glass-ceramic composition and subjected to a heat treatment according to one or more embodiments described herein;

FIG. 6 is a plot of diffuse transmittance (x-axis: Wavelength; y-axis: % Diffuse Transmittance) of example glass-ceramic articles made from a glass-ceramic composition and subjected to a heat treatment according to one or more embodiments described herein;

FIG. 7 is a plot of scatter ratios (x-axis: Wavelength; y-axis: Scatter Ratio) of example glass-ceramic articles made from a glass-ceramic composition and subjected to a heat treatment according to one or more embodiments described herein;

FIG. 8 is a plot of sodium concentration (x-axis: Depth; y-axis: Na₂O concentration) of example glass-ceramic articles made from a glass-ceramic composition and subjected to a heat treatment according to one or more embodiments described herein;

FIG. 9 is a plot of stress (x-axis: Depth; y-axis: Stress) of example glass-ceramic articles made from a glass-ceramic composition and subjected to a heat treatment according to one or more embodiments described herein; and

FIG. 10 is a plot of central tension (x-axis: Depth; y-axis: Central Tension) of example glass-ceramic articles made from a glass-ceramic composition and subjected to a heat treatment according to one or more embodiments described herein.

### DETAILED DESCRIPTION

Reference will now be made in detail to various embodiments of transparent glass-ceramic articles having improved mechanical durability. According to embodiments, a glass-ceramic article includes: greater than or equal to 40 wt % and less than or equal to 60 wt % SiO₂; greater than or equal to 18 wt % and less than or equal to 35 wt % Al₂O₃; greater than or equal to 12 wt % and less than or equal to 16 wt % B₂O₃; greater than or equal to 0 wt % and less than or equal to 4 wt % Li₂O; greater than or equal to 0 wt % and less than or equal to 5 wt % Na₂O; greater than or equal to 0 wt % and less than or equal to 5 wt % K₂O; greater than or equal to 0 wt % and less than or equal to 15 wt % ZnO; and greater than or equal to 0 wt % and less than or equal 8 wt % MgO. The sum of Li₂O and Na₂O in the glass-ceramic article may be greater than or equal to 1 wt % and less than or equal to 8 wt %. The sum of MgO and ZnO in the glass-ceramic article may be greater than or equal to 3 wt % and less than or equal to 20 wt %. A predominate crystalline phase of the glass-ceramic article may comprise a mullite-type structure. Various embodiments of ion exchangeable glass-ceramic compositions and methods of forming glass-ceramic articles therefrom will be referred to herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply ab solute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

The terms “0 wt %,” and “free,” when used to describe the concentration and/or absence of a particular constituent component in a glass-ceramic composition, means that the constituent component is not intentionally added to the glass-ceramic composition. However, the glass-ceramic composition may contain traces of the constituent component as a contaminant or tramp in amounts of less than 0.1 wt %.

In the embodiments of the glass-ceramic compositions or glass-ceramic articles described herein, the concentrations of constituent components (e.g., SiO₂, Al₂O₃, and the like) are specified in weight percent (wt %) on an oxide basis, unless otherwise specified.

The fracture toughness is measured using the double torsion technique described in ASTM STP 559, entitled, “Double Torsion Technique as a Universal Fracture Toughness Test Method,” the contents of which are incorporated herein by reference in their entirety.

X-ray diffraction (XRD) spectrum, as described herein, is measured with a D8 ENDEAVOR X-ray Diffraction system with a LYNXEYE XE-T detector manufactured by Bruker Corporation (Billerica, Mass.).

Transmittance data (total transmittance and diffuse transmittance) is measured with a Lambda 950 UV/Vis Spectrophotometer manufactured by PerkinElmer Inc. (Waltham, Mass. USA). The Lambda 950 apparatus was fitted with a 150 mm integrating sphere. Data was collected using an open beam baseline and a Spectralon® reference reflectance disk. For total transmittance (Total Tx), the sample is fixed at the integrating sphere entry point. For diffuse transmittance (Diffuse Tx), the Spectralon® reference reflectance disk over the sphere exit port is removed to allow on-axis light to exit the sphere and enter a light trap. A zero offset measurement is made, with no sample, of the diffuse portion to determine efficiency of the light trap. To correct diffuse transmittance measurements, the zero offset contribution is subtracted from the sample measurement using the equation: Diffuse Tx=Diffuse Measured−(Zero Offset*(Total Tx/100)). The scatter ratio is measured for all wavelengths as: (% Diffuse Tx/% Total Tx).

The term “average transmittance,” as used herein, refers to the average of transmittance measurements made within a given wavelength range with each whole numbered wavelength weighted equally. In the embodiments described herein, the “average transmittance” is reported over the wavelength range from 400 nm to 800 nm (inclusive of endpoints).

The term “transparent,” when used to describe a glass-ceramic article formed of a glass-ceramic composition described herein, means that the glass-ceramic article has an average transmittance of greater than or equal to 85% when measured at normal incidence for light in a wavelength range from 400 nm to 800 nm (inclusive of endpoints) at an article thickness of 0.8 mm.

The term “transparent haze,” when used to describe a glass-ceramic article formed of a glass-ceramic composition described herein, means that the glass-ceramic article has an average transmittance of greater than or equal to 70% and less than 85% when measured at normal incidence for light in a wavelength range from 400 nm to 800 nm (inclusive of endpoints) at an article thickness of 0.8 mm.

The term “translucent,” when used to describe a glass-ceramic article formed of a glass-ceramic composition described herein, means that the glass-ceramic article has an average transmittance greater than or equal to 20% and less than 70% when measured at normal incidence for light in a wavelength range from 400 nm to 800 nm (inclusive of endpoints) at an article thickness of 0.8 mm.

The term “opaque,” when used to describe a glass-ceramic article formed of a glass-ceramic composition herein, means that the glass-ceramic composition has an average transmittance less than 20% when measured at normal incidence for light in a wavelength range from 400 nm to 800 nm (inclusive of endpoints) at an article thickness of 0.8 mm.

Electron diffraction images using scanning electron microscopy (SEM), as shown and described herein, are taken with a ZEISS GeminiSEM 500 Scanning Electron Microscope at a working distance (WD) of 4.7 mm, an electron high tension (EHT) of 3.00, and high vacuum mode.

The term “melting point,” as used herein, refers to the temperature at which the viscosity of the glass-ceramic composition is 200 poise.

The term “softening point,” as used herein, refers to the temperature at which the viscosity of the glass-ceramic composition is 1×10⁷⁶ poise. The softening point is measured according to the parallel plate viscosity method which measures the viscosity of inorganic glass from 10⁷ to 10⁹ poise as a function of temperature, similar to ASTM C1351M.

The term “liquidus viscosity,” as used herein, refers to the viscosity of the glass-ceramic composition at the onset of devitrification (i.e., at the liquidus temperature as determined with the gradient furnace method according to ASTM C829-81).

The elastic modulus (also referred to as Young's modulus) of the glass-ceramic article, as described herein, is provided in units of gigapascals (GPa) and is measured in accordance with ASTM C623.

The term “CTE,” as used herein, refers to the average coefficient of thermal expansion of the glass-ceramic article between 0° C. and 300° C. (inclusive of endpoints), with each whole numbered wavelength weighted equally.

The term “glass-ceramic article,” as used herein” refers to materials produced through controlled crystallization of glass. In embodiments, glass-ceramics have about 1% to about 99% crystallinity.

Surface compressive stress is measured with a surface stress meter (FSM) such as commercially available instruments such as the FSM-6000, manufactured by Orihara Industrial Co., Ltd. (Japan). Surface stress measurements rely upon the measurement of the stress optical coefficient (SOC), which is related to the birefringence of the glass-ceramic article. SOC, in turn, is measured according to Procedure C (Glass Disc Method) described in ASTM standard C770-16, entitled “Standard Test Method for Measurement of Glass Stress-Optical Coefficient,” the contents of which are incorporated herein by reference in their entirety. Depth of compression (DOC) is measured with the FSM in conjunction with a scatter light polariscope (SCALP) technique known in the art. FSM measures the depth of compression for potassium ion exchange and SCALP measures the depth of compression for sodium ion exchange. The maximum central tension (CT) values are measured using a SCALP technique known in the art.

The phrase “depth of compression” and “DOC” refer to the position in the glass-ceramic article where compressive stress transitions to tensile stress.

The composition profile, as described herein, is measured using a JEOL 8900 Electron Micropobe.

The term “mullite-type,” when used to describe a crystalline phase of a glass-ceramic article formed of a glass-ceramic composition herein, refers to mullite, boron mullite, and metastable zinc and magnesium-containing mullite solid solutions.

Glass-ceramic articles generally have improved fracture toughness relative to articles formed from glass due to the presence of crystalline grains, which impede crack growth, and relatively high elastic modulus. However, because of the microstructure inherent to glass-ceramic articles, it may be difficult to achieve the desired transparency. Moreover, alkali oxides present in the glass-ceramic composition may be included in the crystalline phase after heat treatment and may not be available for ion exchange.

Disclosed herein are glass-ceramic compositions and glass-ceramic articles formed therefrom which mitigate the aforementioned problems. Specifically, the glass-ceramic compositions described herein comprise a relatively high amount of Al₂O₃ and alkali oxides, such as Li₂O and Na₂O, resulting in transparent, mullite-type glass-ceramic articles having a relatively high amount of Li₂O and/or Na₂O present in the residual glass phase. Thus, the residual glass phase, which is also relatively high in Al₂O₃, may be easily ion exchanged. Moreover, the anisotropic nature of acicular orthorhombic mullite-type nanocrystals may aid in improving the fracture toughness of the glass-ceramic article. The relatively high Al₂O₃ content as well as the presence of the high modulus mullite-type crystalline phase may result in a relatively high elastic modulus compared to articles formed from glass alone.

The glass-ceramic compositions described herein may be described as aluminoborosilicate glass-ceramic compositions and comprise SiO₂, Al₂O₃, and B₂O₃. In addition to SiO₂, Al₂O₃, and B₂O₃, the glass-ceramic compositions herein also include alkali oxides, such as Li₂O and Na₂O, to enable the ion exchangeability of glass-ceramic articles formed from the glass-ceramic compositions. The glass-ceramic compositions described herein further include divalent cation oxides, such as ZnO and MgO, to assist in charge balancing the Al₂O₃ in the composition and thereby achieve the desired crystalline phase (and the desired amount of the crystalline phase) in the resulting glass-ceramic article.

SiO₂ is the primary glass former in the glass-ceramic compositions described herein and may function to stabilize the network structure of the glass-ceramic articles. The amount of SiO₂ in the glass-ceramic compositions should be sufficiently high (e.g., greater than or equal to 40 wt %) to form the crystalline phase when the glass-ceramic composition is subjected to heat treatment to convert the glass-ceramic composition to a glass-ceramic article. The amount of SiO₂ may be limited (e.g., less than or equal to 60 wt %) to control the melting point of the glass-ceramic composition, as the melting temperature of pure SiO₂ or high SiO₂ glasses is undesirably high. Thus, limiting the amount of SiO₂ may aid in improving the meltability and the formability of the resulting glass-ceramic article.

Accordingly, in embodiments, the glass-ceramic composition may comprise greater than or equal to 40 wt % and less than or equal to 60 wt % SiO₂. In embodiments, the glass-ceramic composition may comprise greater than or equal to 40 wt % and less than or equal to 55 wt % SiO₂. In embodiments, the glass-ceramic composition may comprise greater than or equal to 43 wt % and less than or equal to 50 wt % SiO₂. In embodiments, the amount of SiO₂ in the glass-ceramic composition may be greater than or equal to 40 wt %, greater than or equal to 43 wt %, or even greater than or equal to 45 wt %. In embodiments, the amount of SiO₂ in the glass-ceramic composition may be less than or equal to 60 wt %, less than or equal to 55 wt %, or even less than or equal to 50 wt %. In embodiments, the amount of SiO₂ in the glass-ceramic composition may be may be greater than or equal to 40 wt % and less than or equal to 60 wt %, greater than or equal to 40 wt % and less than or equal to 55 wt %, greater than or equal to 40 wt % and less than or equal to 50 wt %, greater than or equal to 43 wt % and less than or equal to 60 wt %, greater than or equal to 43 wt % and less than or equal to 55 wt %, greater than or equal to 43 wt % and less than or equal to 50 wt %, greater than or equal to 45 wt % and less than or equal to 60 wt %, greater than or equal to 45 wt % and less than or equal to 55 wt %, or even greater than or equal to 45 wt % and less than or equal to 50 wt %, or any and all sub-ranges formed from any of these endpoints.

Like SiO₂, Al₂O₃ may also stabilize the glass network and additionally provides improved mechanical properties and chemical durability to the resulting glass-ceramic article. The amount of Al₂O₃ may also be tailored to the control the viscosity of the glass-ceramic composition. However, if the amount of Al₂O₃ is too high, the viscosity of the melt may increase. The amount of Al₂O₃ should be sufficiently high (e.g., greater than or equal to 18 wt %) such that the resulting glass-ceramic article has the desired fracture toughness (e.g., greater than or equal to 0.90 MPa·m^{1/2}). However, if the amount of Al₂O₃ is too high (e.g., greater than 35 wt %), the viscosity of the melt may increase, thereby diminishing the formability of the resulting glass-ceramic article. In embodiments, the glass-ceramic composition may comprise greater than or equal to 18 wt % and less than or equal to 35 wt % Al₂O₃. In embodiments, the glass-ceramic composition may comprise greater than or equal to 20 wt % and less than or equal to 30 wt % Al₂O₃. In embodiments, the amount of Al₂O₃ in the glass-ceramic composition may be greater than or equal to 18 wt %, greater than or equal to 20 wt %, or even greater than or equal to 22 wt %. In embodiments, the amount of Al₂O₃ in the glass-ceramic composition may be less than or equal to 35 wt %, less than or equal to 30 wt %, or even less than or equal to 28 wt %. In embodiments, the amount of Al₂O₃ in the glass-ceramic composition may be greater than or equal to 18 wt % and less than or equal to 35 wt %, greater than or equal to 18 wt % and less than or equal to 30 wt %, greater than or equal to 18 wt % and less than or equal to 28 wt %, greater than or equal to 20 wt % and less than or equal to 35 wt %, greater than or equal to 20 wt % and less than or equal to 30 wt %, greater than or equal to 20 wt % and less than or equal to 28 wt %, greater than or equal to 22 wt % and less than or equal to 35 wt %, greater than or equal to 22 wt % and less than or equal to 30 wt %, or even greater than or equal to 22 wt % and less than or equal to 28 wt %, or any and all sub-ranges formed from any of these endpoints.

B₂O₃ decreases the melting temperature of the glass-ceramic composition.

Furthermore, the addition of B₂O₃ in the glass-ceramic composition helps achieve an interlocking crystal microstructure when the glass-ceramic compositions are subjected to heat treatment to form a glass-ceramic article. In addition, B₂O₃ may also improve the damage resistance of the resulting glass-ceramic article. When boron in the residual glass phase present after heat treatment is not charge balanced by alkali oxides or divalent cation oxides (such as MgO, CaO, SrO, BaO, and ZnO), the boron will be in a trigonal-coordination state (or three-coordinated boron), which opens up the structure of the glass. The network around these three-coordinated boron atoms is not as rigid as tetrahedrally coordinated (or four-coordinated) boron. Without being bound by theory, it is believed that glass-ceramic articles that include three-coordinated boron can tolerate some degree of deformation before crack formation compared to four-coordinated boron. By tolerating some deformation, the Vickers indentation crack initiation threshold values increase. Fracture toughness of the glass-ceramic articles that include three-coordinated boron may also increase. The amount of B₂O₃ should be sufficiently high (e.g., greater than or equal to 12 wt %) to improve formability and increase the fracture toughness of the resulting glass-ceramic article. However, if B₂O₃ is too high, the chemical durability and liquidus viscosity may diminish and volatilization and evaporation of B₂O₃ during melting becomes difficult to control. Therefore, the amount of B₂O₃ may be limited (e.g., less than or equal to 16 wt %) to maintain chemical durability and manufacturability of the glass-ceramic composition.

In embodiments, the glass-ceramic composition may comprise greater than or equal to 12 wt % B₂O₃ and less than or equal to 16 wt % B₂O₃. In embodiments, the glass-ceramic composition may comprise greater than or equal to 12.5 wt % and less than or equal to 16 wt % B₂O₃. In embodiments, the glass-ceramic composition may comprise greater than or equal to 13 wt % and less than or equal to 15.5 wt % B₂O₃. In embodiments, the amount of B₂O₃ in the glass-ceramic composition may be greater than or equal to 12 wt %, greater than or equal to 12.5 wt %, greater than or equal to 13 wt %, or even greater than or equal to 13.5 wt. In embodiments, the amount of B₂O₃ in the glass-ceramic composition may be less than or equal to 16 wt % or even less than or equal to 15.5 wt %. In embodiments, the amount of B₂O₃ in the glass-ceramic composition may be greater than or equal to 12 wt % and less than or equal to 16 wt %, greater than or equal to 12 wt % and less than or equal to 15.5 wt %, greater than or equal to 12.5 wt % and less than or equal to 16 wt %, greater than or equal to 12.5 wt % and less than or equal to 15.5 wt %, greater than or equal to 13 wt % and less than or equal to 16 wt %, greater than or equal to 13 wt % and less than or equal to 15.5 wt %, greater than or equal to 13.5 wt % and less than or equal to 16 wt %, or even greater than or equal to 13.5 wt % and less than or equal to 15.5 wt %, or any and all sub-ranges formed from any of these endpoints.

As described hereinabove, the glass-ceramic compositions may contain alkali oxides, such as Li₂O and Na₂O, to enable the ion exchangeability of the glass-ceramic composition. Li₂O aids in the ion exchangeability of the glass-ceramic composition and also reduces the softening point of the glass-ceramic composition thereby increasing the formability of the resulting glass-ceramic article. In embodiments, the glass-ceramic composition may comprise greater than or equal to 0 wt % and less than or equal to 4 wt % Li₂O. In embodiments, the amount of Li₂O in the glass-ceramic composition may be greater than or equal to 0 wt %, greater than or equal to 0.5 wt %, greater than or equal to 1 wt %, greater than or equal to 1.2 wt %, or even greater than or equal to 1.4 wt %. In embodiments, the amount of Li₂O in the glass-ceramic composition may be less than or equal to 4 wt %, less than or equal to 3 wt %, less than or equal to 2.5 wt %, or even less than or equal to 2 wt %. In embodiments, the amount of Li₂O in the glass-ceramic composition may be greater than or equal to 0 wt % and less than or equal to 4 wt %, greater than or equal to 0 wt % and less than or equal to 3 wt %, greater than or equal to 0 wt % and less than or equal to 2.5 wt %, greater than or equal to 0 wt % and less than or equal to 2 wt %, greater than or equal to 0.5 wt % and less than or equal to 4 wt %, greater than or equal to 0.5 wt % and less than or equal to 3 wt %, greater than or equal to 0.5 wt % and less than or equal to 2.5 wt %, greater than or equal to 0.5 wt % and less than or equal to 2 wt %, greater than or equal to 1 wt % and less than or equal to 4 wt %, greater than or equal to 1 wt % and less than or equal to 3 wt %, greater than or equal to 1 wt % and less than or equal to 2.5 wt %, greater than or equal to 1 wt % and less than or equal to 2 wt %, greater than or equal to 1.2 wt % and less than or equal to 4 wt %, greater than or equal to 1.2 wt % and less than or equal to 3 wt %, greater than or equal to 1.2 wt % and less than or equal to 2.5 wt %, greater than or equal to 1.2 wt % and less than or equal to 2 wt %, greater than or equal to 1.2 wt % and less than or equal to 4 wt %, greater than or equal to 1.4 wt % and less than or equal to 3 wt %, greater than or equal to 1.4 wt % and less than or equal to 2.5 wt %, or even greater than or equal to 1.4 wt % and less than or equal to 2 wt %, or any and all sub-ranges formed from any of these endpoints.

In addition to aiding in ion exchangeability of the glass-ceramic composition, Na₂O decreases the melting point and improves formability of the resulting glass-ceramic article. In embodiments, the glass-ceramic composition may comprise greater than or equal to 0 wt % and less than or equal to 5 wt % Na₂O. In embodiments, the amount of Na₂O in the glass-ceramic composition may be greater than or equal to 0 wt %, greater than or equal to 1 wt %, greater than or equal to 1.5 wt %, or even greater than or equal to 2 wt %. In embodiments, the amount of Na₂O in the glass-ceramic composition may be less than or equal to 5 wt %, less than or equal to 4.5 wt %, or even less than or equal to 4 wt %. In embodiments, the amount of Na₂O in the glass-ceramic composition may be greater than or equal to 0 wt % and less than or equal to 5 wt %, greater than or equal to 0 wt % and less than or equal to 4.5 wt %, greater than or equal to 0 wt % and less than or equal to 4 wt %, greater than or equal to 1 wt % and less than or equal to 5 wt %, greater than or equal to 1 wt % and less than or equal to 4.5 wt %, greater than or equal to 1 wt % and less than or equal to 4 wt %, greater than or equal to 1.5 wt % and less than or equal to 5 wt %, greater than or equal to 1.5 wt % and less than or equal to 4.5 wt %, greater than or equal to 1.5 wt % and less than or equal to 4 wt %, greater than or equal to 2 wt % and less than or equal to 5 wt %, greater than or equal to 2 wt % and less than or equal to 4.5 wt %, or even greater than or equal to 2 wt % and less than or equal to 4 wt %, or any and all sub-ranges formed from any of these endpoints.

The total amount of Li₂O and Na₂O in the glass-ceramic composition may be controlled to regulate the ion exchange process. The total amount of Li₂O and Na₂O should be sufficiently high (e.g., greater than or equal to 1 wt %) to enable the ion exchangeability of the glass-ceramic composition. However, if the total amount of Li₂O and Na₂O in the glass-ceramic composition is too high (e.g., greater than 8 wt %), a transparent glass-ceramic article may not be achieved. Accordingly, in embodiments, the total amount of Li₂O and Na₂O in the glass-ceramic composition (i.e., Li₂O (wt %)+Na₂O (wt %)) may be greater than or equal to 1 wt % and less than or equal to 8 wt %. In embodiments, the total amount of Li₂O and Na₂O in the glass-ceramic composition may be greater than or equal to 1.2 wt % and less than or equal to 6 wt %. In embodiments, the total amount of Li₂O and Na₂O in the glass-ceramic composition may be greater than or equal to 1.4 wt % and less than or equal to 5 wt %. In embodiments, the total amount of Li₂O and Na₂O in the glass-ceramic composition may be greater than or equal to 1 wt %, greater than or equal to 1.2 wt %, or even greater than or equal to 1.4 wt %. In embodiments, the total amount of Li₂O and Na₂O in the glass-ceramic composition may be less than or equal to 8 wt %, less than or equal to 6 wt %, less than or equal to 5 wt %, or even less than or equal to 4 wt %. In embodiments, the total amount of Li₂O and Na₂O in the glass-ceramic composition may be greater than or equal to 1 wt % and less than or equal to 8 wt %, greater than or equal to 1 wt % and less than or equal to 6 wt %, greater than or equal to 1 wt % and less than or equal to 5 wt %, greater than or equal to 1 wt % and less than or equal to 4 wt %, greater than or equal to 1.2 wt % and less than or equal to 8 wt %, greater than or equal to 1.2 wt % and less than or equal to 6 wt %, greater than or equal to 1.2 wt % and less than or equal to 5 wt %, greater than or equal to 1.2 wt % and less than or equal to 4 wt %, greater than or equal to 1.4 wt % and less than or equal to 8 wt %, greater than or equal to 1.4 wt % and less than or equal to 6 wt %, greater than or equal to 1.4 wt % and less than or equal to 5 wt %, or even greater than or equal to 1.4 wt % and less than or equal to 4 wt %, or any and all sub-ranges formed from any of these endpoints.

The glass-ceramic compositions described herein may further comprise alkali metal oxides other than Li₂O and Na₂O, such as K₂O. K₂O promotes ion exchange, increases the depth of compression and decreases the melting point to improve formability of the resulting glass-ceramic article. However, adding K₂O may cause the surface compressive stress and melting point to be too low. In embodiments, the amount of K₂O in the glass-ceramic composition may be greater than or equal to 0 wt % or even greater than or equal to 0.1 wt %. In embodiments, the amount of K₂O in the glass-ceramic composition may be less than or equal to 5 wt %, less than or equal to 3 wt %, less than or equal to 1 wt %, or even less than or equal to 0.5 wt %. In embodiments, the amount of K₂O in the glass-ceramic composition may be greater than or equal to 0 wt % and less than or equal to 5 wt %, greater than or equal to 0.1 wt % and less than or equal to 5 wt %, greater than or equal to 0 wt % and less than or equal to 3 wt %, greater than or equal to 0.1 wt % and less than or equal to 3 wt %, greater than or equal to 0 wt % and less than or equal to 1 wt %, greater than or equal to 0.1 wt % and less than or equal to 1 wt %, greater than or equal to 0 wt % and less than or equal to 0.5 wt %, or even greater than or equal to 0.1 wt % and less than or equal to 0.5 wt %, or any and all sub-ranges formed from any of these endpoints.

The sum of all alkali oxides is expressed herein as R₂O. Specifically, R₂O is the sum (in wt %) of Li₂O, Na₂O, and K₂O (i.e., R₂O═Li₂O (wt %)+Na₂O (wt %)+K₂O (wt %)) present in the glass-ceramic composition. Like B₂O₃, the alkali oxides aid in decreasing the softening point and molding temperature of the glass-ceramic composition, thereby offsetting the increase in the softening point and molding temperature of the glass-ceramic composition due to higher amounts of SiO₂ in the glass-ceramic composition. The decrease in the softening point and molding temperature may be further reduced by including combinations of alkali oxides (e.g., two or more alkali oxides) in the glass-ceramic composition, a phenomenon referred to as the “mixed alkali effect.” However, it has been found that if the amount of alkali oxide is too high, the average coefficient of thermal expansion of the glass-ceramic composition increases to greater than 100×10⁻⁷° C., which may be undesirable.

In embodiments, the amount of R₂O in the glass-ceramic composition may be greater than or equal to 1 wt %, greater than or equal to 1.2 wt %, or even greater than or equal to 1.4 wt %. In embodiments, the total amount of R₂O in the glass-ceramic composition may be less than or equal to 10 wt %, less than or equal to 8 wt %, or even less than or equal to 5 wt %. In embodiments, the total amount of Li₂O and Na₂O in the glass-ceramic composition may be greater than or equal to 1 wt % and less than or equal to 10 wt %, greater than or equal to 1 wt % and less than or equal to 8 wt %, greater than or equal to 1 wt % and less than or equal to 5 wt %, greater than or equal to 1.2 wt % and less than or equal to 10 wt %, greater than or equal to 1.2 wt % and less than or equal to 8 wt %, greater than or equal to 1.2 wt % and less than or equal to 5 wt %, greater than or equal to 1.4 wt % and less than or equal to 10 wt %, greater than or equal to 1.4 wt % and less than or equal to 8 wt %, or even greater than or equal to 1 wt % and less than or equal to 5 wt %, or any and all sub-ranges formed from any of these endpoints.

MgO in the glass-ceramic composition may aid in charge balancing the Al₂O₃ in the glass-ceramic composition. Charge balancing the Al₂O₃ aids in achieving the desired crystalline phase (and the amount of the crystalline phase) in the glass-ceramic article. MgO lowers the viscosity of the glass-ceramic compositions, which enhances the formability, the strain point, and the elastic modulus, and may improve the ion exchangeability of the resulting glass-ceramic article. MgO may be included in the glass-ceramic composition (e.g., in an amount greater than or equal to 0 wt %) to aid in charge balancing the Al₂O₃ and lowering the viscosity of the glass-ceramic composition. However, when too much MgO is added to the glass-ceramic composition (e.g., greater than 8 wt %), the diffusivity of sodium and potassium ions in the glass-ceramic composition decreases which, in turn, adversely impacts the ion exchange performance (i.e., the ability to ion exchange) of the resulting glass-ceramic article.

In embodiments, the glass-ceramic composition may comprise greater than or equal to 0 wt % and less than or equal to 8 wt % MgO. In embodiments, the amount of MgO in the glass-ceramic composition may be greater than or equal to 0 wt %, greater than or equal to 2 wt %, or even greater than or equal to 4 wt %. In embodiments, the amount of MgO in the glass-ceramic composition may be less than or equal to 8 wt % or even less than or equal to 6 wt %. In embodiments, the amount of MgO in the glass-ceramic composition may be greater than or equal to 0 wt % and less than or equal to 8 wt %, greater than or equal to 0 wt % and less than or equal to 6 wt %, greater than or equal to 2 wt % and less than or equal to 8 wt %, greater than or equal to 2 wt % and less than or equal to 6 wt %, greater than or equal to 4 wt % and less than or equal to 8 wt %, or even greater than or equal to 4 wt % and less than or equal to 6 wt %, or any and all sub-ranges formed from any of these endpoints.

Like MgO, ZnO may assist MgO in charge balancing the Al₂O₃ in the composition and thereby achieve the desired crystalline phase (and the amount of the crystalline phase) in the resulting glass-ceramic article. In embodiments, the glass-ceramic composition may comprise greater than or equal to 0 wt % and less than or equal to 15 wt % ZnO. In embodiments, the glass-ceramic composition may comprise greater than or equal to 8 wt % and less than or equal to 15 wt % ZnO. In embodiments, the amount of ZnO in the glass-ceramic composition may be greater than or equal to 0 wt %, greater than or equal to 2 wt %, greater than or equal to 4 wt %, greater than or equal to 6 wt %, or even greater than or equal to 8 wt %. In embodiments, the amount of ZnO in the glass-ceramic composition may be less than or equal to 15 wt %, less than or equal to 13 wt %, or even less than or equal to 11 wt %. In embodiments, the amount of ZnO in the glass-ceramic composition may be greater than or equal to 0 wt % and less than or equal to 15 wt %, greater than or equal to 0 wt % and less than or equal to 13 wt %, greater than or equal to 0 wt % and less than or equal to 11 wt %, greater than or equal to 2 wt % and less than or equal to 15 wt %, greater than or equal to 2 wt % and less than or equal to 13 wt %, greater than or equal to 2 wt % and less than or equal to 11 wt %, greater than or equal to 4 wt % and less than or equal to 15 wt %, greater than or equal to 4 wt % and less than or equal to 13 wt %, greater than or equal to 4 wt % and less than or equal to 11 wt %, greater than or equal to 6 wt % and less than or equal to 15 wt %, greater than or equal to 6 wt % and less than or equal to 13 wt %, greater than or equal to 6 wt % and less than or equal to 11 wt %, greater than or equal to 8 wt % and less than or equal to 15 wt %, greater than or equal to 8 wt % and less than or equal to 13 wt %, or even greater than or equal to 8 wt % and less than or equal to 11 wt %, or any and all sub-ranges formed from any of these endpoints.

The total amount of MgO and ZnO in the glass-ceramic composition may be controlled to assist in charge balancing the Al₂O₃ in the composition and thereby achieve the desired crystalline phase (and the amount of the crystalline phase) in the resulting glass-ceramic article. The total amount of MgO and ZnO in the glass-ceramic composition should be sufficiently high (e.g., greater than or equal to 3 wt %) to enable formation of the desired mullite-type crystalline phase. However, if the total amount of MgO and ZnO is too high (e.g., greater than 20 wt %), the formation of the desired mullite-type crystalline phase may be reduced in favor of other crystalline phases, such as spinel and β-quartz. Accordingly, in embodiments, the total amount of MgO and ZnO in the glass-ceramic composition (i.e., MgO (wt %)+ZnO (wt %)) may be greater than or equal to 3 wt % and less than or equal to 20 wt %. In embodiments, the total amount of MgO and ZnO in the glass-ceramic composition may be greater than or equal to 5 wt % and less than or equal to 18 wt %. In embodiments, the total amount of MgO and ZnO in the glass-ceramic composition may be greater than or equal to 7 wt % and less than or equal to 15 wt %. In embodiments, the total amount of MgO and ZnO in the glass-ceramic composition may be greater than or equal to 3 wt %, greater than or equal to 5 wt %, or even greater than or equal to 7 wt %. In embodiments, the total amount of MgO and ZnO in the glass-ceramic composition may be less than or equal to 20 wt %, less than or equal to 18 wt %, less than or equal to 15 wt %, or even less than or equal to 13 wt %. In embodiments, the total amount of MgO and ZnO in the glass-ceramic composition may be greater than or equal to 3 wt % and less than or equal to 20 wt %, greater than or equal to 3 wt % and less than or equal to 18 wt %, greater than or equal to 3 wt % and less than or equal to 15 wt %, greater than or equal to 3 wt % and less than or equal to 13 wt %, greater than or equal to 5 wt % and less than or equal to 20 wt %, greater than or equal to 5 wt % and less than or equal to 18 wt %, greater than or equal to 5 wt % and less than or equal to 15 wt %, greater than or equal to 5 wt % and less than or equal to 13 wt %, greater than or equal to 7 wt % and less than or equal to 20 wt %, greater than or equal to 7 wt % and less than or equal to 18 wt %, greater than or equal to 7 wt % and less than or equal to 15 wt %, greater than or equal to 7 wt % and less than or equal to 13 wt %, or any and all sub-ranges formed from any of these endpoints.

In embodiments, the glass-ceramic composition may comprise greater than or equal to 0 wt % and less than or equal to 5 wt % CaO. In embodiments, the amount of CaO in the glass-ceramic composition may be greater than or equal to 0 wt %, greater than or equal to 0.1 wt %, greater than or equal to 0.5 wt %, or even greater than or equal to 1 wt %. In embodiments, the amount of CaO in the glass-ceramic composition may be less than or equal to 5 wt % or even less than or equal to 3 wt %. In embodiments, the amount of CaO in the glass-ceramic composition may be greater than or equal to 0 wt % and less than or equal to 5 wt %, greater than or equal to 0 wt % and less than or equal to 3 wt %, greater than or equal to 0.1 wt % and less than or equal to 5 wt %, greater than or equal to 0.1 wt % and less than or equal to 3 wt %, greater than or equal to 0.5 wt % and less than or equal to 5 wt %, greater than or equal to 0.5 wt % and less than or equal to 3 wt %, greater than or equal to 1 wt % and less than or equal to 5 wt %, or even greater than or equal to 1 wt % and less than or equal to 3 wt %, or any and all sub-ranges formed from any of these endpoints. In embodiments, the glass-ceramic composition may be free of CaO.

In embodiments, the glass-ceramic composition may comprise greater than or equal to 0 wt % and less than or equal to 5 wt % SrO. In embodiments, the amount of SrO in the glass-ceramic composition may be greater than or equal to 0 wt %, greater than or equal to 0.1 wt %, greater than or equal to 0.5 wt %, or even greater than or equal to 1 wt %. In embodiments, the amount of SrO in the glass-ceramic composition may be less than or equal to 5 wt % or even less than or equal to 3 wt %. In embodiments, the amount of SrO in the glass-ceramic composition may be greater than or equal to 0 wt % and less than or equal to 5 wt %, greater than or equal to 0 wt % and less than or equal to 3 wt %, greater than or equal to 0.1 wt % and less than or equal to 5 wt %, greater than or equal to 0.1 wt % and less than or equal to 3 wt %, greater than or equal to 0.5 wt % and less than or equal to 5 wt %, greater than or equal to 0.5 wt % and less than or equal to 3 wt %, greater than or equal to 1 wt % and less than or equal to 5 wt %, or even greater than or equal to 1 wt % and less than or equal to 3 wt %, or any and all sub-ranges formed from any of these endpoints. In embodiments, the glass composition may be free of SrO.

In embodiments, the glass-ceramic composition may comprise greater than or equal to 0 wt % and less than or equal to 5 wt % BaO. In embodiments, the amount of BaO in the glass-ceramic composition may be greater than or equal to 0 wt %, greater than or equal to 0.1 wt %, greater than or equal to 0.5 wt %, or even greater than or equal to 1 wt %. In embodiments, the amount of BaO in the glass-ceramic composition may be less than or equal to 5 wt % or even less than or equal to 3 wt %. In embodiments, the amount of BaO in the glass-ceramic composition may be greater than or equal to 0 wt % and less than or equal to 5 wt %, greater than or equal to 0 wt % and less than or equal to 3 wt %, greater than or equal to 0.1 wt % and less than or equal to 5 wt %, greater than or equal to 0.1 wt % and less than or equal to 3 wt %, greater than or equal to 0.5 wt % and less than or equal to 5 wt %, greater than or equal to 0.5 wt % and less than or equal to 3 wt %, greater than or equal to 1 wt % and less than or equal to 5 wt %, or even greater than or equal to 1 wt % and less than or equal to 3 wt %, or any and all sub-ranges formed from any of these endpoints. In embodiments, the glass composition may be free of BaO.

The sum of all divalent cation oxides is expressed herein as RO. Specifically, RO is the sum (in wt %) of MgO, ZnO, CaO, SrO, and BaO (i.e. RO═MgO (wt %)+ZnO (wt %)+CaO (wt %)+SrO (wt %)+BaO (wt %)) present in the glass-ceramic composition. In embodiments the amount of RO in the glass-ceramic composition may be greater than or equal to 3 wt %, greater than or equal to 5 wt %, greater than or equal to 7 wt %, or even greater than or equal to 10 wt %. In embodiments, the amount of RO in the glass-ceramic composition may less than or equal to 20 wt %, less than or equal to 18 wt %, or even less than or equal to 15 wt %. In embodiments, the amount of RO in the glass-ceramic composition may be greater than or equal to 3 wt % and less than or equal to 20 wt %, greater than or equal to 3 wt % and less than or equal to 18 wt %, greater than or equal to 3 wt % and less than or equal to 15 wt %, greater than or equal to 5 wt % and less than or equal to 20 wt %, greater than or equal to 5 wt % and less than or equal to 18 wt %, greater than or equal to 5 wt % and less than or equal to 15 wt %, greater than or equal to 7 wt % and less than or equal to 20 wt %, greater than or equal to 7 wt % and less than or equal to 18 wt %, greater than or equal to 7 wt % and less than or equal to 15 wt %, greater than or equal to 10 wt % and less than or equal to 20 wt %, greater than or equal to 10 wt % and less than or equal to 18 wt %, or even greater than or equal to 10 wt % and less than or equal to 15 wt %, or any and all sub-ranges formed from any of these endpoints.

In embodiments, the total amount of R₂O and RO (i.e., R₂O (wt %)+RO (wt %)) in the glass-ceramic composition may be greater than or equal to 4 wt %, greater than or equal to 7 wt %, or even greater than or equal to 10 wt %. In embodiments, the total amount of R₂O and RO in the glass-ceramic composition may be less than or equal to 30 wt %, less than or equal to 25 wt %, less than or equal to 20 wt %, or even less than or equal to 15 wt %. In embodiments, the total amount of R₂O and RO in the glass-ceramic composition may be greater than or equal to 4 wt % and less than or equal to 30 wt %, greater than or equal to 4 wt % and less than or equal to 25 wt %, greater than or equal to 4 wt % and less than or equal to 20 wt %, greater than or equal to 4 wt % and less than or equal to 15 wt %, greater than or equal to 7 wt % and less than or equal to 30 wt %, greater than or equal to 7 wt % and less than or equal to 25 wt %, greater than or equal to 7 wt % and less than or equal to 20 wt %, greater than or equal to 7 wt % and less than or equal to 15 wt %, greater than or equal to 10 wt % and less than or equal to 30 wt %, greater than or equal to 10 wt % and less than or equal to 25 wt %, greater than or equal to 10 wt % and less than or equal to 20 wt %, or even greater than or equal to 10 wt % and less than or equal to 15 wt %, or any and all sub-ranges formed from any of these endpoints.

In embodiments, the glass-ceramic compositions described herein may be peraluminous (i.e., the weight ratio of the sum of R₂O and RO to Al₂O₃ is less than 1), which may help to form the desired mullite-type crystalline phase as opposed to other crystalline phases, such as spinel or β-quartz. In embodiments, the weight ratio of the sum of R₂O and RO to Al₂O₃ (i.e., (R₂O+RO)/Al₂O₃)) is less than 1.

In embodiments, the glass-ceramic compositions described herein may further include a modifier that assists in equalizing the refractive indices of the crystalline phase and the residual glass phase. In embodiments, the modifier may include Y₂O₃, SrO, B₂O₃, TiO₂, ZrO₂, La₂O₃, GeO₂, or a combination thereof. In embodiments, the amount of the modifier in the glass-ceramic composition may be greater than or equal to 0 wt %, greater than or equal to 0.1 wt %, greater than or equal to 0.5 wt %, or even greater than or equal to 1 wt %. In embodiments, the amount of the modifier in the glass-ceramic composition may be less than or equal to 5 wt % or even less than or equal to 3 wt %. In embodiments, the amount of the modifier in the glass-ceramic composition may be greater than or equal to 0 wt % and less than or equal to 5 wt %, greater than or equal to 0 wt % and less than or equal to 3 wt %, greater than or equal to 0.1 wt % and less than or equal to 5 wt %, greater than or equal to 0.1 wt % and less than or equal to 3 wt %, greater than or equal to 0.5 wt % and less than or equal to 5 wt %, greater than or equal to 0.5 wt % and less than or equal to 3 wt %, greater than or equal to 1 wt % and less than or equal to 5 wt %, or even greater than or equal to 1 wt % and less than or equal to 3 wt %, or any and all sub-ranges formed from any of these endpoints.

In embodiments, the glass-ceramic compositions described herein may further include tramp materials such as TiO₂, MnO, MoO₃, WO₃, La₂O₃, CdO, As₂O₃, Sb₂O₃, sulfur-based compounds, such as sulfates, halogens, or combinations thereof. In embodiments, antimicrobial components, chemical fining agents, or other additional components may be included in the glass-ceramic compositions.

In embodiments, the glass-ceramic compositions may be free of ZrO₂. For example, in embodiments, the glass-ceramic composition may comprise 0 wt % ZrO₂. In embodiments, it may be desirable for the glass-ceramic compositions to be free of As₂O₃. For example, in embodiments, the glass-ceramic composition may comprise 0 wt % As₂O₃. While not wishing to be bound by theory, As₂O₃ may be considered a toxin and elimination of As₂O₃ from the glass-ceramic composition may result in an environmentally friendly (i.e., “green”) glass-ceramic article.

The glass-ceramic articles formed from the glass-ceramic compositions described herein may be any suitable thickness, which may vary depending on the particular application for use of the glass-ceramic article. In embodiments, the glass-ceramic sheet embodiments may have a thickness greater than or equal to 250 μm and less than or equal to 6 mm, greater than or equal to 250 μm and less than or equal to 4 mm, greater than or equal to 250 μm and less than or equal to 2 mm, greater than or equal to 250 μm and less than or equal to 1 mm, greater than or equal to 250 μm and less than or equal to 750 μm, greater than or equal to 250 μm and less than or equal to 500 μm, greater than or equal to 500 μm and less than or equal to 6 mm, greater than or equal to 500 μm and less than or equal to 4 mm, greater than or equal to 500 μm and less than or equal to 2 mm, greater than or equal to 500 μm and less than or equal to 1 mm, greater than or equal to 500 μm and less than or equal to 750 μm, greater than or equal to 750 μm and less than or equal to 6 mm, greater than or equal to 750 μm and less than or equal to 4 mm, greater than or equal to 750 μm and less than or equal to 2 mm, greater than or equal to 750 μm and less than or equal to 1 mm, greater than or equal to 1 mm and less than or equal to 6 mm, greater than or equal to 1 mm and less than or equal to 4 mm, greater than or equal to 1 mm and less than or equal to 2 mm, greater than or equal to 2 mm and less than or equal to 6 mm, greater than or equal to 2 mm and less than or equal to 4 mm, or even greater than or equal to 4 mm and less than or equal to 6 mm, or any and all sub-ranges formed from any of these endpoints.

As discussed hereinabove, glass-ceramic articles formed from the glass-ceramic compositions described herein may have an increased fracture toughness such that the glass-ceramic articles are more resistant to damage. In embodiments, the glass-ceramic article may have a K_{Ic} fracture toughness as measured by a double torsion method greater than or equal to 0.90 MPa·m^{1/2}. In embodiments, the glass-ceramic article may have a K_{Ic} fracture toughness as measured by a double torsion method greater than or equal to 0.90 MPa·m^{1/2}, greater than or equal to 1 MPa·m^{1/2}, or even greater than or equal to 1.1 MPa·m^{1/2}.

In embodiments, a glass-ceramic article may have an elastic modulus greater than or equal to 50 MPa and less than or equal to 100 MPa. In embodiments, the glass-ceramic article may have an elastic modulus greater than or equal to 50 MPa, greater than or equal to 60 MPa, greater than or equal to 70 MPa, or even greater than or equal to 80 MPa. In embodiments, the glass-ceramic article may have an elastic modulus less than or equal to 100 MPa or even less than or equal to 95 MPa. In embodiments, the glass-ceramic article may have an elastic modulus greater than or equal to 50 MPa and less than or equal to 100 MPa, greater than or equal to 50 MPa and less than or equal to 95 MPa, greater than or equal to 60 MPa and less than or equal to 100 MPa, greater than or equal to 60 MPa and less than or equal to 95 MPa, greater than or equal to 70 MPa and less than or equal to 100 MPa, greater than or equal to 70 MPa and less than or equal to 95 MPa, greater than or equal to 80 MPa and less than or equal to 100 MPa, or even greater than or equal to 80 MPa and less than or equal to 95 MPa, or any and all sub-ranges formed from any of these endpoints.

In embodiments, a glass-ceramic article may have an average transmittance greater than or equal to 70% and less than or equal to 95% of light over the wavelength range of 400 nm to 800 nm as measured at an article thickness of 0.8 mm. In embodiments, the glass-ceramic article may have an average transmittance greater than or equal to 70%, greater than or equal to 75%, greater than or equal to 80%, or even greater than or equal to 85% of light over the wavelength range of 400 nm to 800 nm as measured at an article thickness of 0.8 mm. In embodiments, the glass-ceramic article may have an average transmittance less than or equal to 95% or even less than or equal to 90% of light over the wavelength range of 400 nm to 800 nm as measured at an article thickness of 0.8 mm. In embodiments, the glass-ceramic article may have an average transmittance greater than or equal to 70% and less than or equal to 95%, greater than or equal to 70% and less than or equal to 90%, greater than or equal to 75% and less than or equal to 95%, greater than or equal to 75% and less than or equal to 90%, greater than or equal to 80% and less than or equal to 95%, greater than or equal to 80% and less than or equal to 90%, greater than or equal to 85% and less than or equal to 95%, or even greater than or equal to 85% and less than or equal to 90%, or any and all sub-ranges formed from any of these endpoints of light over the wavelength range of 400 nm to 800 nm as measured at an article thickness of 0.8 mm. In embodiments, the glass-ceramic article may be transparent or transparent haze.

In embodiments, the glass-ceramic article may have an average diffuse transmittance greater than or equal to 0.5% or even greater than or equal to 1% of light over the wavelength range of 400 nm to 800 nm as measured at an article thickness of 0.8 mm. In embodiments, the glass-ceramic article may have an average diffuse transmittance less than or equal to 10% or even less than or equal to 5% of light over the wavelength range of 400 nm to 800 nm as measured at an article thickness of 0.8 mm. In embodiments, the glass-ceramic article may have an average diffuse transmittance greater than or equal to 0.5% and less than or equal to 10%, greater than or equal to 0.5% and less than or equal to 5%, greater than or equal to 1% and less than or equal to 10%, or even greater than or equal to 1% and less than or equal to 5%, or any and all sub-ranges formed from any of these endpoints of light over the wavelength range of 400 nm to 800 nm as measured at an article thickness of 0.8 mm.

In embodiments, the glass-ceramic article may have a coefficient of thermal expansion (CTE) less than or equal to 50×10⁻⁷/° C. In embodiments, the glass-ceramic article may have a coefficient of thermal expansion (CTE) less than or equal to 50×10⁻⁷/° C., less than or equal to 47×10⁻⁷/° C., less than or equal to 45×10⁻⁷/° C., or even less than or equal to 43×10⁻⁷/° C.

In embodiments, the glass-ceramic articles may have a liquidus viscosity greater than or equal to 100 P, greater than or equal to 250 P, greater than or equal to 500 P, greater than or equal to 1 kP, greater than or equal to 10 kP, or even greater than or equal to 25 kP. In embodiments, the glass-ceramic article may have a liquidus viscosity greater than or equal to 100 P and less than or equal to 25 kP, greater than or equal to 100 P and less than or equal to 10 kP, greater than or equal to 100 P and less than or equal to 1 kP, greater than or equal to 100 P and less than or equal to 500 P, greater than or equal to 100 P and less than or equal to 250 P, greater than or equal to 250 P and less than or equal to 25 kP, greater than or equal to 250 P and less than or equal to 10 kP, greater than or equal to 250 P and less than or equal to 1 kP, greater than or equal to 250 P and less than or equal to 500 P, greater than or equal to 500 P and less than or equal to 25 kP, greater than or equal to 500 P and less than or equal to 10 kP, greater than or equal to 500 P and less than or equal to 1 kP, greater than or equal to 1 kP and less than or equal to 25 kP, greater than or equal to 1 kP and less than or equal to 10 kP, or even greater than or equal to 10 kP and less than or equal to 25 kP, or any and all sub-ranges formed from any of these endpoints. This range of viscosities allows the glass-ceramic articles to be formed into sheets by a variety of different techniques including, without limitation fusion forming, slot draw, floating, rolling, and other sheet-forming processes known to those in the art. However, it should be understood that other processes may be used for forming other articles (i.e., other than sheets).

In embodiments, the glass-ceramic compositions described herein are ion exchangeable to facilitate strengthening the glass-ceramic article. In typical ion exchange processes, smaller metal ions in the glass-ceramic article are replaced or “exchanged” with larger metal ions of the same valence within a layer that is close to the outer surface of the glass-ceramic article. The replacement of smaller ions with larger ions creates a compressive stress within the layer of the glass-ceramic article. In embodiments, the metal ions are monovalent metal ions (e.g., Li⁺, Na⁺, K⁺, and the like), and ion exchange is accomplished by immersing the glass-ceramic article in a bath comprising at least one molten salt of the larger metal ion that is to replace the smaller metal ion in the glass-ceramic article. Alternatively, other monovalent ions such as Ag⁺, Tl⁺, Cu⁺, and the like may be exchanged for monovalent ions. The ion exchange process or processes that are used to strengthen the glass-ceramic article may include, but are not limited to, immersion in a single bath or multiple baths of like or different compositions with washing and/or annealing steps between immersions.

Upon exposure to the glass-ceramic article, the ion exchange solution (e.g., KNO₃ and/or NaNO₃ molten salt bath) may, according to embodiments, be at a temperature greater than or equal to 350° C. and less than or equal to 500° C., greater than or equal to 360° C. and less than or equal to 450° C., greater than or equal to 370° C. and less than or equal to 440° C., greater than or equal to 360° C. and less than or equal to 420° C., greater than or equal to 370° C. and less than or equal to 400° C., greater than or equal to 375° C. and less than or equal to 475° C., greater than or equal to 400° C. and less than or equal to 500° C., greater than or equal to 410° C. and less than or equal to 490° C., greater than or equal to 420° C. and less than or equal to 480° C., greater than or equal to 430° C. and less than or equal to 470° C., or even greater than or equal to 440° C. and less than or equal to 460° C., or any and all sub-ranges between the foregoing values. In embodiments, the glass-ceramic article may be exposed to the ion exchange solution for a duration greater than or equal to 2 hours and less than or equal to 48 hours, greater than or equal to 2 hours and less than or equal to 24 hours, greater than or equal to 2 hours and less than or equal to 12 hours, greater than or equal to 2 hours and less than or equal to 6 hours, greater than or equal to 8 hours and less than or equal to 44 hours, greater than or equal to 12 hours and less than or equal to 40 hours, greater than or equal to 16 hours and less than or equal to 36 hours, greater than or equal to 20 hours and less than or equal to 32 hours, or even greater than or equal to 24 hours and less than or equal to 28 hours, or any and all sub-ranges between the foregoing values.

The resulting compressive stress layer may have a depth (also referred to as a “depth of compression” or “DOC”) greater than or equal to 100 μm on the surface of the glass-ceramic article in 2 hours of ion exchange time. In embodiments, the glass-ceramic articles may be ion exchanged to achieve a depth of compression greater than or equal to 10 μm, greater than or equal to 20 μm, greater than or equal to 30 μm, greater than or equal to 40 μm, greater than or equal to 50 μm, greater than or equal to 60 μm, greater than or equal to 70 μm, greater than or equal to 80 μm, greater than or equal to 90 μm, or even greater than or equal to 100 μm. In embodiments, the glass-ceramic articles have a thickness “t” and may be ion exchanged to achieve a depth of compression greater than or equal to 0.1 t, greater than or equal to 0.13 t, or even greater than or equal to 0.15 t.

The development of this surface compression layer is beneficial for achieving a better crack resistance and higher flexural strength compared to non-ion-exchanged materials. The surface compression layer has a higher concentration of the ions exchanged into the glass-ceramic article in comparison to the concentration of the ions exchanged into the glass-ceramic article for the body (i.e., the area not including the surface compression) of the glass-ceramic article.

In embodiments, the glass-ceramic article made from a glass-ceramic composition described herein may have a surface compressive stress after ion exchange strengthening greater than or equal to 20 MPa, greater than or equal to 50 MPa, greater than or equal to 75 MPa, greater than or equal to 100 MPa, greater than or equal to 250 MPa, greater than or equal to 500 MPa, greater than or equal to 750 MPa, or even greater than or equal to 1 GPa. In embodiments, the glass-ceramic article may have a surface compressive stress after ion exchange strengthening greater than or equal to 20 MPa and less than or equal to 1 GPa, greater than or equal to 20 MPa and less than or equal to 750 MPa, greater than or equal to 20 MPa and less than or equal to 500 MPa, greater than or equal to 20 MPa and less than or equal to 250 MPa, greater than or equal to 50 MPa and less than or equal to 1 GPa, greater than or equal to 50 MPa and less than or equal to 750 MPa, greater than or equal to 50 MPa and less than or equal to 500 MPa, greater than or equal to 50 MPa and less than or equal to 250 MPa, greater than or equal to 75 MPa and less than or equal to 1 GPa, greater than or equal to 75 MPa and less than or equal to 750 MPa, greater than or equal to 75 MPa and less than or equal to 500 MPa, greater than or equal to 75 MPa and less than or equal to 250 MPa, greater than or equal to 100 MPa and less than or equal to 1 GPa, greater than or equal to 100 MPa and less than or equal to 750 MPa, greater than or equal to 100 MPa and less than or equal to 500 MPa, greater than or equal to 100 MPa and less than or equal to 250 MPa, greater than or equal to 250 MPa and less than or equal to 1 GPa, greater than or equal to 250 MPa and less than or equal to 750 MPa, greater than or equal to 250 MPa and less than or equal to 500 MPa, greater than or equal to 500 MPa and less than or equal to 1 GPa, greater than or equal to 500 MPa and less than or equal to 750 MPa, or even greater than or equal to 750 MPa and less than or equal to 1 GPa, or any and all sub-ranges formed from any of these endpoints.

In embodiments, the glass-ceramic article made from a glass-ceramic composition described herein may have a central tension after ion exchange strengthening greater than or equal to 10 MPa, greater than or equal to 25 MPa, or even greater than or equal to 50 MPa. In embodiments, the glass-ceramic article made from a glass-ceramic composition described herein may have a central tension after ion exchange strengthening less than or equal to 250 MPa, less than or equal to 200 MPa, or even less than or equal to 150 MPa. In embodiments, the glass-ceramic article made from a glass-ceramic composition described herein may have a central tension after ion exchange strengthening greater than or equal to 10 MPa and less than or equal to 250 MPa, greater than or equal to 25 MPa and less than or equal to 250 MPa, greater than or equal to 50 MPa and less than or equal to 250 MPa, greater than or equal to 10 MPa and less than or equal to 200 MPa, greater than or equal to 25 MPa and less than or equal to 200 MPa, greater than or equal to 50 MPa and less than or equal to 200 MPa, greater than or equal to 10 MPa and less than or equal to 150 MPa, greater than or equal to 25 MPa and less than or equal to 150 MPa, or even greater than or equal to 50 MPa and less than or equal to 150 MPa, or any and all sub-ranges formed from any of these endpoints.

In embodiments, the processes for making the glass-ceramic article includes heat treating the glass-ceramic composition in an oven at one or more preselected temperatures for one or more preselected times to induce glass homogenization and crystallization (i.e., nucleation and growth) of one or more crystalline phases (e.g., having one or more compositions, amounts, morphologies, sizes or size distributions, etc.). In embodiments, the heat treatment may include (i) heating a glass-ceramic composition in an oven at a rate greater than or equal to 1° C./min and less than or equal to 10° C./min to a nucleation temperature; (ii) maintaining the glass-ceramic composition at the nucleation temperature in the oven for time greater than or equal to 0.25 hour and less than or equal to 4 hours to produce a nucleated crystallizable glass; (iii) heating the nucleated crystallizable glass in the oven at a rate greater than or equal to 1° C./min and less than or equal to 10° C./min to a crystallization temperature; (iv) maintaining the nucleated crystallizable glass at the crystallization temperature in the oven for a time greater than or equal to 0.25 hour and less than or equal to 4 hours to produce the glass-ceramic article; and (v) cooling the glass-ceramic article to room temperature.

In embodiments, the nucleation temperature may be greater than or equal to 600° C. and less than or equal to 900° C. In embodiments, the nucleation temperature may be greater than or equal to 600° C. or even greater than or equal to 650° C. In embodiments, the nucleation temperature may be less than or equal to 900° C. or even less than or equal to 800° C. In embodiments, the nucleation temperature may be greater than or equal to 600° C. and less than or equal to 900° C., greater than or equal to 600° C. and less than or equal to 800° C., greater than or equal to 650° C. and less than or equal to 900° C., or even greater than or equal to 650° C. and less than or equal to 800° C., or any and all sub-ranges formed from any of these endpoints.

In embodiments, the crystallization temperature may be greater than or equal to 700° C. and less than or equal to 1000° C. In embodiments, the crystallization temperature may be greater than or equal to 700° C. or even greater than or equal to 750° C. In embodiments, the crystallization temperature may be less than or equal to 1000° C. or even less than or equal to 900° C. In embodiments, the crystallization temperature may be greater than or equal to 700° C. and less than or equal to 1000° C., greater than or equal to 700° C. and less than or equal to 900° C., greater than or equal to 750° C. and less than or equal to 1000° C., or even greater than or equal to 750° C. and less than or equal to 900° C., or any and all sub-ranges formed from any of these endpoints.

One skilled in the art would understand that the heating rates, nucleation temperature, and crystallization temperature described herein refer to the heating rate and temperature of the oven in which the glass-ceramic composition is being heat treated.

In addition to the glass-ceramic compositions, temperature-temporal profiles of heat treatment steps of heating to the crystallization temperature and maintaining the temperature at the crystallization temperature are judiciously prescribed so as to produce one or more of the following desired attributes: crystalline phase(s) of the glass-ceramic article, proportions of one or more major crystalline phases and/or one or more minor crystalline phases and residual glass phases, crystal phase assemblages of one or more predominate crystalline phases and/or one or more minor crystalline phases and residual glass phases, and grain sizes or grain size distribution among one or more major crystalline phases and/or one or more minor crystalline phases, which in turn may influence the final integrity, quality, color, and/or opacity of the resulting glass-ceramic article.

The glass-ceramic articles described herein may include a crystalline phase and a residual glass phase. In embodiments, a predominate crystalline phase (i.e., greater than or equal to 50% of the crystalline phase) of the glass-ceramic article comprises a mullite-type structure. In embodiments, the crystalline phase may include mullite, vranaite, or a combination thereof.

In embodiments, the glass-ceramic articles may include greater than or equal to 50 wt % of the crystalline phase by weight of the glass-ceramic article (i.e., wt %) and less than or equal to 50 wt % of the residual glass phase, greater than or equal to 60 wt % of the crystalline phase and less than or equal to 40 wt % of the residual glass phase, greater than or equal to 70 wt % of the crystalline phase and less than or equal to 30 wt % of the residual glass phase, greater than or equal to 80 wt % of the crystalline phase and less than or equal to 20 wt % of the residual glass phase, or even greater than or equal to 90 wt % of the crystalline phase and less than or equal to 10 wt %, or any and all sub-ranges formed from any of these endpoints as determined according to Rietveld analysis of the XRD spectrum.

The resulting glass-ceramic article may be provided as a sheet, which may then be reformed by pressing, blowing, bending, sagging, vacuum forming, or other means into curved or bend pieces of uniform thickness. Reforming may be done before thermally treating or the forming step may also serve as a thermal treatment step in which both forming and thermal treating are performed substantially simultaneously.

The glass-ceramic articles described herein may be used for a variety of applications including, for example, for cover glass or glass backplane applications in consumer or commercial electronic devices including, for example, LCD and LED displays, computer monitors, and automated teller machines (ATMs); for touch screen or touch sensor applications, for portable electronic devices including, for example, mobile telephones, personal media players, watches and tablet computers; for integrated circuit applications including, for example, semiconductor wafers; for photovoltaic applications; for architectural glass applications; for automotive or vehicular glass applications; or for commercial or household appliance applications. In embodiments, a consumer electronic device (e.g., smartphones, tablet computers, watches, personal computers, ultrabooks, televisions, and cameras), an architectural glass, and/or an automotive glass may comprise a glass-article article as described herein.

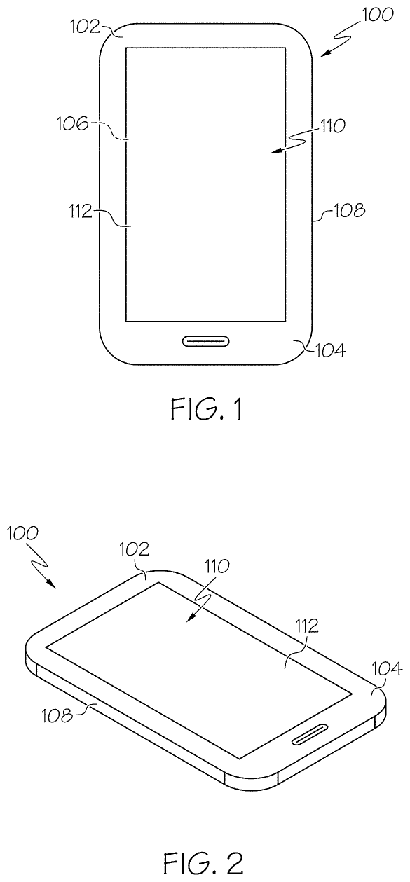

An exemplary article incorporating any of the glass-ceramic articles disclosed herein is shown in FIGS. 1 and 2. Specifically, FIGS. 1 and 2 show a consumer electronic device 100 including a housing 102 having front 104, back 106, and side surfaces 108; electrical components (not shown) that are at least partially inside or entirely within the housing and including at least a controller, a memory, and a display 110 at or adjacent to the front surface of the housing; and a cover substrate 112 at or over the front surface of the housing such that it is over the display. In embodiments, at least one of the cover substrate 112 and a portion of housing 102 may include any of the glass-ceramic articles disclosed herein.

### Examples

In order that various embodiments be more readily understood, reference is made to the following examples, which are intended to illustrate various embodiments of the glass-ceramic articles described herein.

Table 1 shows example glass-ceramic compositions (in terms of wt %). Table 2 shows the heat treatment schedule for achieving example glass-ceramic articles, and the respective properties of the glass-ceramic articles. Glass-ceramic articles were formed having the example glass-ceramic compositions 1-6 listed in Table 1.

TABLE 1

| Example | 1 | 2 | 3 | 4 | 5 | 6 |
|---|---|---|---|---|---|---|
| SiO₂ | 47.49 | 47.07 | 46.65 | 47.78 | 47.57 | 47.42 |
| Al₂O₃ | 25.25 | 25.04 | 24.81 | 25.42 | 25.30 | 25.23 |
| B₂O₃ | 15.16 | 15.02 | 14.89 | 15.25 | 15.18 | 15.13 |
| Na₂O | 2.00 | 2.86 | 3.71 | 0 | 0 | 1.44 |
| Li₂O | 0 | 0 | 0 | 1.40 | 1.82 | 0.69 |
| ZnO | 10.10 | 10.01 | 9.93 | 10.16 | 10.13 | 10.09 |
| Li₂O + Na₂O | 2.00 | 2.86 | 3.71 | 1.40 | 1.82 | 2.13 |
| MgO + ZnO | 10.10 | 10.01 | 9.93 | 10.16 | 10.13 | 10.09 |
| R₂O | 2.00 | 2.86 | 3.71 | 1.40 | 1.82 | 2.13 |
| RO | 10.10 | 10.01 | 9.93 | 10.16 | 10.13 | 10.09 |
| R₂O + RO | 12.10 | 12.87 | 13.64 | 11.56 | 11.95 | 12.22 |
| (R₂O + RO)/Al₂O₃ | 0.48 | 0.51 | 0.55 | 0.45 | 0.47 | 0.48 |

TABLE 2

| Example | 1 | 2 | 3 | 4 |
|---|---|---|---|---|
| Nucleation hold | 750° C. | 750° C. | 750° C. | 750° C. |
| | for 4 hr | for 4 hr | for 4 hr | for 4 hr |
| Crystallization | 850° C. | 850° C. | 850° C. | 850° C. |
| hold | for 2 hr | for 2 hr | for 2 hr | for 2 hr |
| Appearance | Trans- | Trans- | Trans- | Trans- |
| | parent | lucent | lucent | parent |
| | haze | | | haze |
| K_{Ic} (CN) | — | — | — | — |
| (MPa · m^{1/2}) | | | | |
| Elastic modulus (Gpa) | 88.3 | 86.9 | 84.8 | 93.9 |
| CTE (10⁻⁷/° C.) | — | — | — | — |

| Example | 5 | 5 | 6 |
|---|---|---|---|
| Nucleation hold | 675° C. | 750° C. | 750° C. |
| | for 4 hr | for 4 hr | for 4 hr |
| Crystallization | 775° C. | 850° C. | 850° C. |
| hold | for 2 hr | for 2 hr | for 2 hr |
| Appearance | Trans- | Trans- | Trans- |
| | parent | parent | parent |
| | | | haze |
| K_{Ic} (CN) | — | 1.26 | — |
| (MPa · m^{1/2}) | | | |
| Elastic modulus (Gpa) | — | 92.3 | 91.8 |
| CTE (10⁻⁷/° C.) | — | 42.6 | — |

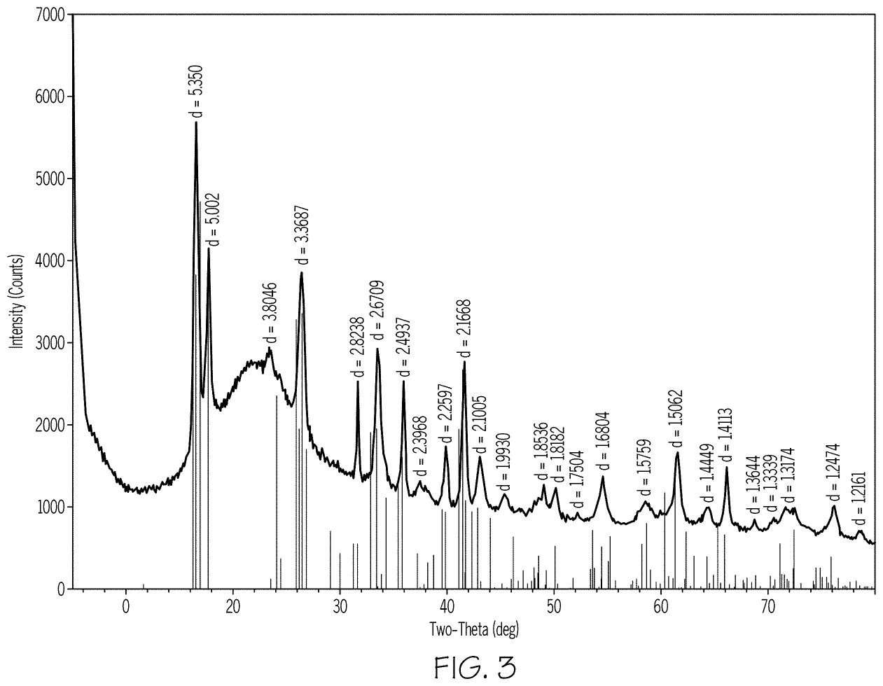

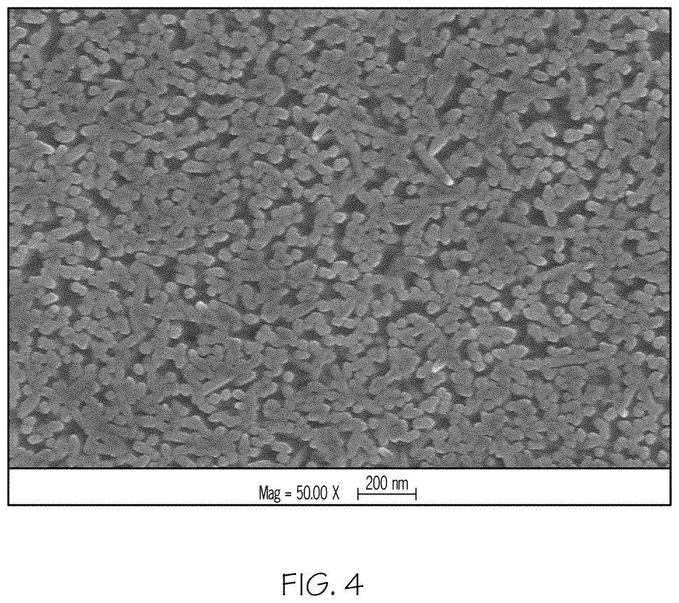

Referring now to FIG. 3, the XRD spectrum for an example glass-ceramic article formed from example glass-ceramic composition 5 subjected to a nucleation hold in an oven at 675° C. for 4 hours and a crystallization hold in the oven at 775° C. for 2 hours includes peaks evidencing the presence of a boron mullite crystalline phase and a vranaite crystalline phase. The boron mullite crystalline phase and vranaite crystalline phases are non-alkali containing. Referring now to FIG. 4, the SEM image for the example glass-ceramic article formed from glass-ceramic composition 5 subjected to a nucleation hold in an oven at 675° C. for 4 hours and a crystallization hold in the oven at 775° C. for 2 hours shows the boron mullite crystals and the vranaite crystals in a residual glass matrix. The crystals are acicular, which may contribute to the increased mechanical durability of the glass-ceramic article. As indicated by FIGS. 3 and 4, the glass-ceramic compositions described herein may be heat treated to form glass-ceramic articles having one or more non-alkali containing crystalline phases such that the alkali present in the glass-ceramic composition may be left in the residual glass phase after crystallization to be ion exchanged.

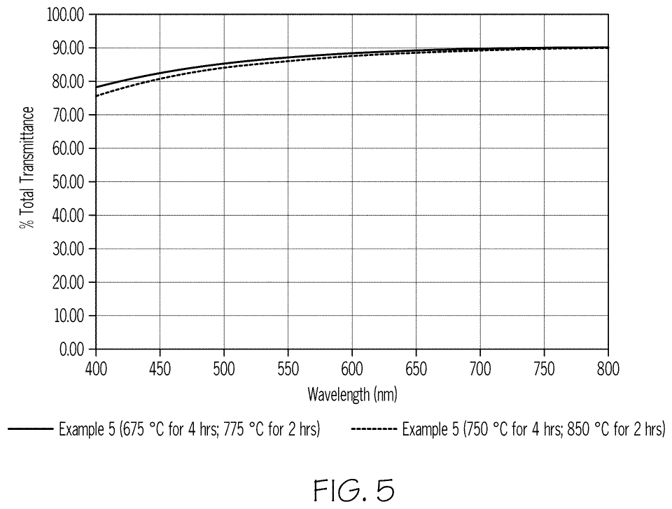

Referring now to FIGS. 5-7, the total transmittance, diffuse transmittance, and scatter ratio of glass-ceramic articles having a 0.8 mm thickness and formed from example glass-ceramic composition 5 subjected to a nucleation hold in an oven at 675° C. for 4 hours and a crystallization hold in the oven at 775° C. for 2 hours and example glass-ceramic composition 5 subjected to a nucleation hold in an oven at 750° C. for 4 hours and a crystallization hold in the oven at 850° C. for 2 hours are measured for light having a wavelength from 400 nm to 800 nm.

As shown in FIG. 5, the example glass-ceramic article made from example glass-ceramic composition 5 subjected to a nucleation hold in an oven at 675° C. for 4 hours and a crystallization hold in the oven at 775° C. for 2 hours has an average total transmittance of 87.9% over the wavelength range of 400 nm to 800 nm, indicating that the specified heat treatment of example glass-ceramic composition 5 resulted in a transparent glass-ceramic article. The example glass-ceramic article made from example glass-ceramic composition 5 subjected to a nucleation hold in an oven at 750° C. for 4 hours and a crystallization hold in the oven at 850° C. for 2 hours has an average total transmittance of 86.70% over the wavelength range of 400 nm to 800 nm, indicating that the specified heat treatment of example glass-ceramic composition 5 resulted in a transparent glass-ceramic article. As indicated by FIG. 5, the glass-ceramic articles formed from the glass-ceramic compositions described herein may be subjected to certain ion exchange conditions to achieve the desired transmittance (i.e., appearance). That is, more specifically, the temperature of the ion exchange may be used to vary the resulting transmittance.

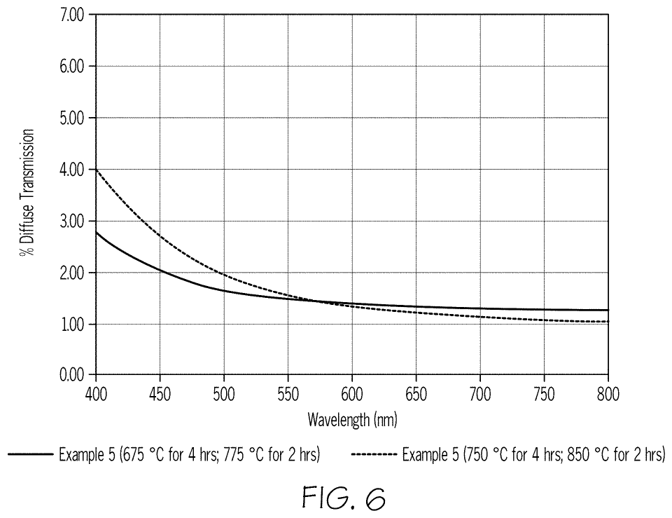

As shown in FIG. 6, the example glass-ceramic article made from example glass-ceramic composition 5 subjected to a nucleation hold in an oven at 675° C. for 4 hours and a crystallization hold in the oven at 775° C. for 2 hours has an average diffuse transmittance of 1.56 over the wavelength range of 400 nm to 800 nm. The example glass-ceramic article made from example glass-ceramic composition 5 subjected to a nucleation hold in an oven at 750° C. for 4 hours and a crystallization hold in the oven at 850° C. for 2 hours has an average diffuse transmittance of 1.68 over the wavelength range of 400 nm to 800 nm.

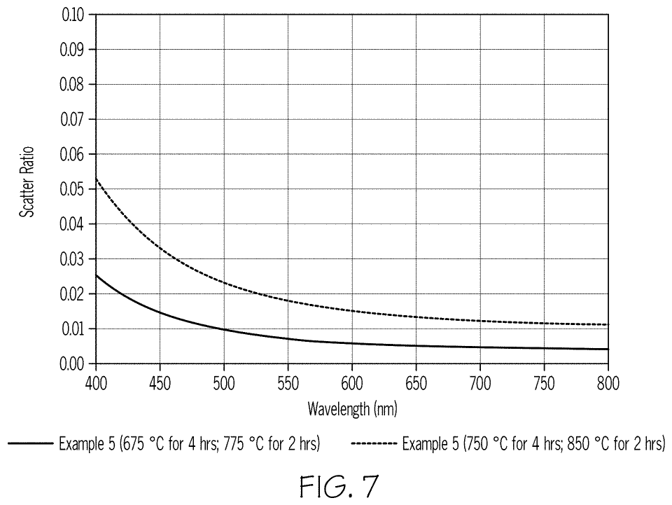

As shown in FIG. 7, the example glass-ceramic article made from example glass-ceramic composition 5 subjected to a nucleation hold in an oven at 675° C. for 4 hours and a crystallization hold in the oven at 775° C. for 2 hours has an average scatter ratio of 0.0085 over the wavelength range of 400 nm to 800 nm. The example glass-ceramic article made from example glass-ceramic composition 5 subjected to a nucleation hold in an oven at 750° C. for 4 hours and a crystallization hold in the oven at 850° C. for 2 hours has an average scatter ratio of 0.0199 over the wavelength range of 400 nm to 800 nm.

As indicated by FIGS. 6 and 7, the glass-ceramic articles formed from the glass-ceramic compositions described herein may be subjected to certain ion exchange conditions to achieve relatively low diffuse transmittance and scatter ratios, which means less scattering of light. While not wishing to be bound by theory, the relatively low diffuse transmittance and scatter ratios may be due to the similarity of the refractive indices of the crystalline phases and/or due to the smaller crystal sizes.

Referring now to FIG. 8, example glass-ceramic articles having a thickness of 0.8 mm and formed from example glass-ceramic composition 5 subjected to a nucleation hold in an oven at 750° C. for 4 hours and a crystallization hold in the oven at 850° C. for 2 hours were ion exchanged. The example glass-ceramic articles were ion exchanged in a 100% NaNO₃ molten salt bath for 4 hours and 17.5 hours, respectively. As shown in FIG. 8, the example glass-ceramic article ion exchanged for 17.5 hours exhibits a near parabolic profile of sodium ions exchanged into the article.

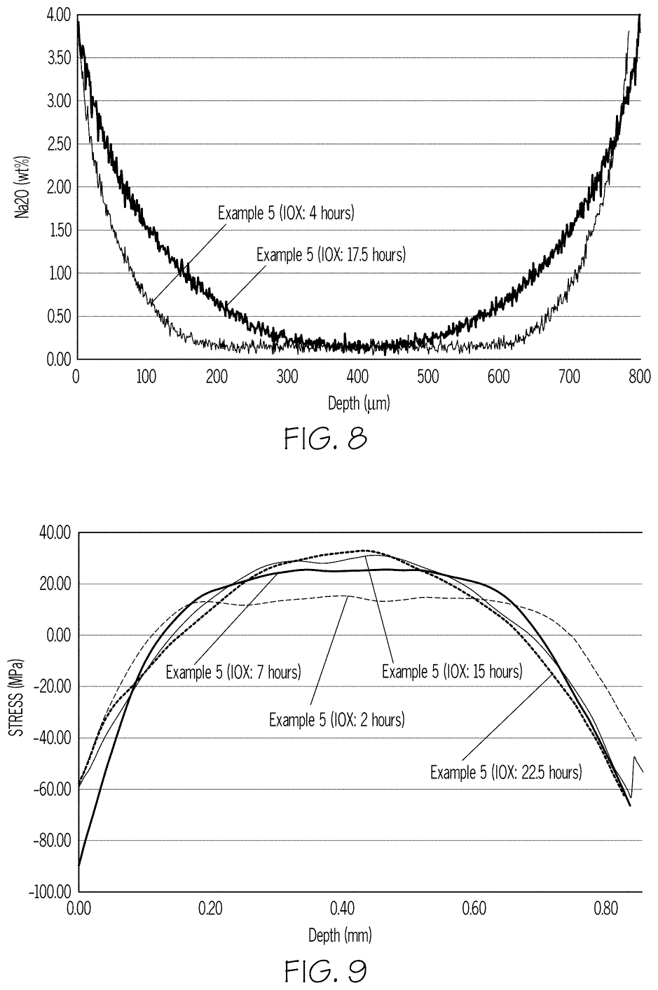

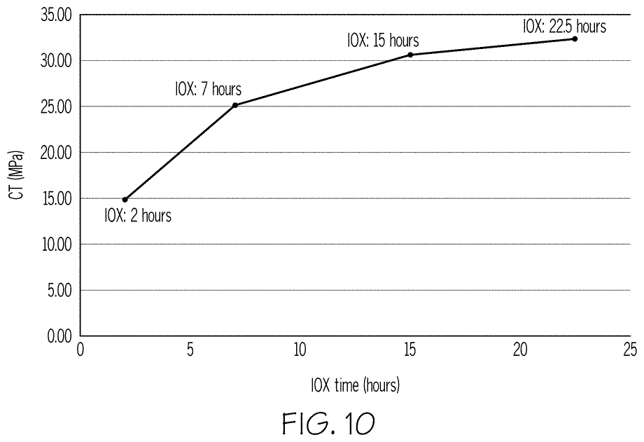

Referring now to FIGS. 9 and 10 and Table 3, example glass-ceramic articles having a thickness of 0.8 mm and formed from example glass-ceramic composition 5 subjected to a nucleation hold in an oven at 675° C. for 4 hours and a crystallization hold in the oven at 775° C. for 2 hours were ion exchanged. As shown in FIG. 9, the articles were ion exchanged in a 100% NaNO₃ molten salt bath for 2 hours, 7 hours, 15 hours, and 22.5 hours, respectively, and achieved various thickness stress profiles as measured using SCALP. As shown in FIG. 10, central tension of the glass-ceramic articles increases with ion exchange time. As shown in Table 3, depth of compression (in terms of a percentage of the thickness (“% t”) of the ion exchanged glass article) increases with ion exchange time.

TABLE 3

| | 5 (IOX: | 5 (IOX: | 5 (IOX: | 5 (IOX: |
|---|---|---|---|---|
| Example | 2 hours) | 7 hours) | 15 hours) | 22.5 hours) |
| DOC (% t) | 0.13 | 0.15 | 0.17 | 0.18 |
| Thickness (mm) | 0.84 | 0.84 | 0.84 | 0.84 |

As indicated by FIGS. 8-10 and Table 3, the glass-ceramic articles formed from the glass-ceramic compositions described herein may be subjected to certain ion exchange conditions to achieve the desired composition/stress profile and central tension.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A glass-ceramic article comprising:
greater than or equal to 40 wt % and less than or equal to 60 wt % SiO₂;
greater than or equal to 18 wt % and less than or equal to 35 wt % Al₂O₃;
greater than or equal to 12 wt % and less than or equal to 16 wt % B₂O₃;
greater than or equal to 0 wt % and less than or equal to 4 wt % Li₂O;
greater than or equal to 0 wt % and less than or equal to 5 wt % Na₂O;
greater than or equal to 0 wt % and less than or equal to 5 wt % K₂O;
greater than or equal to 0 wt % and less than or equal to 15 wt % ZnO; and
greater than or equal to 0 wt % and less than or equal 8 wt % MgO, wherein:
Li₂O+Na₂O is greater than or equal to 1 wt % and less than or equal to 8 wt %;
MgO+ZnO is greater than or equal to 3 wt % and less than or equal to 20 wt %; and
a predominate crystalline phase of the glass-ceramic article comprises a mullite-type structure.

2. The glass-ceramic article of claim 1, wherein the glass-ceramic article comprises greater than or equal to 12.5 wt % and less than or equal to 16 wt % B₂O₃.

3. The glass-ceramic article of claim 1, wherein Li₂O+Na₂O is greater than or equal to 1.2 wt % and less than or equal to 6 wt %.

4. The glass-ceramic article of claim 1, wherein MgO+ZnO is greater than or equal to 5 wt % and less than or equal to 18 wt %.

5. The glass-ceramic article of claim 1, wherein the glass-ceramic article comprises greater than or equal to 8 wt % and less than or equal to 15 wt % ZnO.

6. The glass-ceramic article of claim 1, wherein (R₂O+RO)/Al₂O₃ is less than 1.

7. The glass-ceramic article of claim 1, wherein the glass-ceramic article is free of ZrO₂.

8. The glass-ceramic article of claim 1, wherein the glass-ceramic article is free of As₂O₃.

9. The glass-ceramic article of claim 1, wherein a K_{Ic} fracture toughness of the glass-ceramic article as measured by a double torsion method is greater than or equal to 0.90 MPa·m^{1/2}.

10. The glass-ceramic article of claim 1, wherein an elastic modulus of the glass-ceramic article is greater than or equal to 50 GPa and less than or equal to 100 GPa.

11. The glass-ceramic article of claim 1, wherein an average transmittance of the glass-ceramic article is greater than or equal to 70% and less than or equal to 95% of light over the wavelength range of 400 nm to 800 nm as measured at an article thickness of 0.8 mm.

12. The glass-ceramic article of claim 1, wherein a coefficient of thermal expansion (CTE) of the glass-ceramic article is less than or equal to 50×10⁻⁷/° C.

13. A method of forming a glass-ceramic article, the method comprising:
heating a glass-ceramic composition in an oven at a rate greater than or equal to 1° C./min and less than or equal to 10° C./min to a nucleation temperature, wherein the glass-ceramic composition comprises:
greater than or equal to 40 wt % and less than or equal to 60 wt % SiO₂;
greater than or equal to 18 wt % and less than or equal to 35 wt % Al₂O₃;
greater than or equal to 12 wt % and less than or equal to 16 wt % B₂O₃;
greater than or equal to 0 wt % and less than or equal to 4 wt % Li₂O;
greater than or equal to 0 wt % and less than or equal to 5 wt % Na₂O;
greater than or equal to 0 wt % and less than or equal to 5 wt % K₂O;
greater than or equal to 0 wt % and less than or equal to 15 wt % ZnO; and
greater than or equal to 0 wt % and less than or equal 8 wt % MgO, wherein:
Li₂O+Na₂O is greater than or equal to 1 wt % and less than or equal to 8 wt %; and
MgO+ZnO is greater than or equal to 3 wt % and less than or equal to 20 wt %;
maintaining the glass-ceramic composition at the nucleation temperature in the oven for time greater than or equal to 0.25 hour and less than or equal to 4 hours to produce a nucleated crystallizable glass;
heating the nucleated crystallizable glass in the oven at a rate greater than or equal to 1° C./min and less than or equal to 10° C./min to a crystallization temperature;
maintaining the nucleated crystallizable glass at the crystallization temperature in the oven for a time greater than or equal to 0.25 hour and less than or equal to 4 hours to produce the glass-ceramic article, wherein a predominate crystalline phase of the glass-ceramic article comprises a mullite-type structure; and
cooling the glass-ceramic article to room temperature.

14. The method of claim 13, wherein the nucleation temperature is greater than or equal to 600° C. and less than or equal to 900° C.

15. The method of claim 13, wherein the crystallization temperature is greater than or equal to 700° C. and less than or equal to 1000° C.

16. The method of claim 13, further comprising strengthening the glass-ceramic article in an ion exchange bath.

17. The method of claim 13, wherein the glass-ceramic article has a K_{Ic} fracture toughness as measured by a double torsion method greater than or equal to 0.90 MPa·m^{1/2}.

18. The method of claim 13, wherein the glass-ceramic article has an elastic modulus greater than or equal to 50 GPa and less than or equal to 100 GPa.

19. The method of claim 13, wherein the glass-ceramic article has an average transmittance greater than or equal to 70% and less than or equal to 95% of light over the wavelength range of 400 nm to 800 nm as measured at an article thickness of 0.8 mm.

20. A consumer electronic device, comprising:
a housing having a front surface, a back surface, and side surfaces;
electrical components provided at least partially within the housing, the electrical components including at least a controller, a memory, and a display, the display being provided at or adjacent the front surface of the housing; and
the glass-ceramic article of claim 1 disposed over the display.
